(19) United States
(12) Patent Application Publication
(10) Pub. No.: US 2005/0098786 A1
(43) Pub. Date: May 12, 2005

(54) Semiconductor light emitting device and method of manufacturing the same

(75) Inventors: Hironobu Sai, Kyoto (JP); Yoshiaki Oku, Kyoto (JP)

Correspondence Address: BURNS DOANE SWECKER & MATHIS L L P, POST OFFICE BOX 1404, ALEXANDRIA, VA, 22313-1404, US

(73) Assignee: ROHM CO., LTD.

(21) Appl. No.: 10/673,188

(22) Filed: Sep. 30, 2003

(30) Foreign Application Priority Data
Sep. 30, 2002 (JP) P. 2002-286995

(51) Int. Cl. H01L 27/15

(52) U.S. Cl. 257/79

(57) ABSTRACT

In a semiconductor light emitting device including a mesa section having at least a sandwich structure of an n-type clad layer, an active layer and a p-type clad layer which are constituted by compound semiconductor layers formed on a substrate, and an inorganic insulating film 22 formed to cover the mesa section excluding a contact region, the inorganic insulating film is constituted by an inorganic insulating film having a vacancy rate of 50% or more.

### BACKGROUND OF THE INVENTION

1. Field of the Invention

The present invention relates to a semiconductor light emitting device and a method of manufacturing the semiconductor light emitting device, and more particularly to a reduction in the parasitic capacitance of an electrode pad section.

2. Description of the Related Art

A semiconductor light emitting device using a compound semiconductor, particularly, a compound semiconductor laser has widely been used in an optical apparatus. FIG. 11 is a perspective view typically showing an example of the compound semiconductor laser and FIG. 12 is a sectional view showing a main part. As shown in the drawings, a compound semiconductor laser 1 is constituted by a first electrode 3, a second electrode 2 and a plurality of compound semiconductor layers provided between the first electrode 3 and the second electrode 2.

The compound semiconductor layer is constituted by a semiconductor substrate 4 (for example, N⁺-GaAs), a lower multilayer reflecting film (for example, AlₓGa₁₋ₓAs) 5 formed on the upper surface of the semiconductor substrate 4, a quantum well active layer 7 formed on the lower multilayer reflecting film 5 through a lower clad layer (for example, Al_{y}Ga_{1-y}As) 6, and an upper clad layer (for example, AlᵣGa₁₋ᵣAs) 9 formed on the upper surface of the quantum well active layer 7 through an upper clad layer (for example, AlᵤGa₁₋ᵤAs) 8, for example. Moreover, a current constricting layer 10 formed by an AlGaAs oxide layer which is opened over a predetermined width and has a current constricting section 10a is provided on the upper clad layer 8. Furthermore, the second electrode 2 is formed through a contact layer 11 provided on the upper multilayer reflecting film 9 and the first electrode 3 is provided on the electrode formation surface of the semiconductor substrate 4.

A mesa section thus formed is covered with an insulating film 12 formed of polyimide and an electrode pad 13 connected to the second electrode 2 formed on the top surface of the mesa section is provided on the insulating film 12. Since the second electrode 2 is constituted by a shielding film, it has an opening to be a light emitting region.

The semiconductor laser 1 having such a structure is fabricated by the following method, for example.

First of all, in the layer structure shown in FIG. 12, the layers are formed up to the quantum well active layer 7 excluding the first electrode 3 by an MOCVD method.

Then, the layers are sequentially provided on the upper clad layer 8 by the MOCVD method again and the first electrode 3 and the second electrode 2 are finally deposited. The current constricting layer 10 is obtained by providing an aluminum arsenide (AlAs) film and then introducing steam from the end face of an element and oxidizing the aluminum arsenide film to form aluminum oxide (Al₂O₃), for example, and a portion in which steam oxidation does not occur (a portion in which the aluminum arsenide remains) acts as the current constricting section 10a.

A polyimide film to be the interlayer insulating film 12 is formed and a contact is formed thereon, and a wiring section including the electrode pad 13 is formed to come in contact with the top surface of the mesa section to be a light emitting surface.

In such a surface emission type semiconductor laser, a luminous intensity depends on a current density. Therefore, it is necessary to reduce the area of a light emitting section. The area of the mesa section is increasingly reduced and the area of the electrode pad is more increased than that of the mesa section. Accordingly, a capacity formed between the electrode pad and the substrate (which will be hereinafter referred to as a pad capacity) is large. Consequently, there is a problem in that an increase in the modulating speed of the laser is impeded.

Moreover, a region surrounding the current constricting section 10a is aluminum oxide formed by the selective oxidation of AlGaAs and arsenic is desorbed as AsH₃. Consequently, a porous state is brought so that a mechanical strength becomes small.

Thus, the mechanical strength of the mesa section itself is small and the area of the mesa section is also reduced. Consequently, it is desirable that the mesa section should be reinforced by the insulating film 12 formed to surround the mesa section. However, the polyimide has a great difference in a coefficient of thermal expansion from the mesa section. Moreover, the thickness of the polyimide is reduced to ½ in sintering at approximately 350° C. For this reason, a great stress is applied to the mesa section in both film formation and its use. Consequently, peeling is generated on an interface, resulting in a deterioration in a reliability in some cases.

### SUMMARY OF THE INVENTION

The invention has been made in consideration of the actual circumstances and has an object to provide a semiconductor light emitting device capable of reducing the pad capacity of an electrode pad and increasing a modulating speed.

Moreover, it is another object of the invention to provide a semiconductor light emitting device which reduces a stress to be applied to a mesa section in both film formation and use and has a high reliability.

The invention provides a semiconductor light emitting device comprising a mesa section having at least a sandwich structure of an n-type clad layer, an active layer and a p-type clad layer which are constituted by compound semiconductor layers formed on a substrate, and an inorganic insulating film formed to cover the mesa section excluding a contact region, wherein the inorganic insulating film is constituted by an inorganic insulating film having a vacancy rate of 50% or more.

The mesa section excluding the contact region is covered with the inorganic insulating film having a vacancy rate of 50% or more. Therefore, it is possible to provide a semiconductor light emitting device which can reduce a capacity in a pad section and has a high modulating speed.

Moreover, it is desirable that the inorganic insulating film should include an inorganic insulating film having at least two kinds of periodic porous structures. Consequently, it is possible to obtain an insulating film having a greater mechanical strength.

Furthermore, it is desirable that the mesa section should include a surface emission structure having an electrode in a top portion and should comprise a semiconductor layer provided with an active layer having a quantum well structure constituted by a compound semiconductor, and a pad to come in contact with the electrode should be provided on the inorganic insulating film.

According to such a structure, the dielectric constant of the inorganic insulating film is low. Consequently, the capacity can be reduced. Moreover, the mesa section having a small mechanical strength is covered with the inorganic insulating film. Therefore, it is possible to obtain the structure of the mesa section in which the mechanical strength can be enhanced and a high reliability can be obtained.

Moreover, it is desirable that the inorganic insulating film should have a periodic porous structure formed on the surface of the substrate and including a cylindrical vacancy oriented in parallel with the surface of the substrate.

According to such a structure, the vacancy is oriented in parallel with the surface of the substrate. Therefore, a low dielectric constant is uniformly given in a perpendicular direction to the surface of the substrate. In the case in which the inorganic insulating film is used as an insulating layer, particularly, it is possible to employ such a close structure without having an opening portion for an upper wiring and a lower wiring. Thus, it is possible to provide an effective thin film having a low dielectric constant which is excellent in a moisture resistance and has a high reliability.

It is desirable that there should be included a plurality of periodic porous structure domains formed on the surface of the substrate and having a cylindrical vacancy oriented in one direction in parallel with the surface of the substrate and the porous structure domains which are adjacent to each other should be oriented in different directions from each other.

According to such a structure, the porous structures are oriented in different directions for each domain, which makes it possible to close the opening portions of the vacancies each other. Thus, a thin film having an ultimately low dielectric constant can be obtained, which has an excellent moisture resistance being almost equal to the moisture resistance of a fine film and has an excellent mechanical strength with the periodic structure. Furthermore, a space provided between the layers is supported by the adjacent layer. Consequently, a layered periodic porous shape which is supposed to be usually unstable can be constructed with a stable and excellent mechanical strength.

It is desirable that the inorganic insulating film should include a periodic porous structure domain in which a layered vacancy is periodically oriented in one direction in parallel with the surface of the substrate.

According to such a structure, the layered vacancy is oriented in parallel with the surface of the substrate. Therefore, a low dielectric constant is uniformly given in a perpendicular direction to the surface of the substrate. In the case in which the inorganic insulating film is used for an insulating layer, particularly, it is possible to employ such a closed structure without having an opening portion for an upper wiring and a lower wiring. Thus, it is possible to provide an effective thin film having a low dielectric constant which is excellent in a moisture resistance and has a high reliability. With this structure, a higher vacancy rate can be obtained and a dielectric constant can be more reduced as compared with a structure having a cylindrical vacancy.

In a method according to the invention, the step of forming the inorganic insulating film comprises the step of generating a precursor solution containing a silica derivative and a surface active agent, the precrosslinking step of raising a temperature of the precursor solution and starting a crosslinking reaction, the contact step of causing the precursor solution starting the crosslinking reaction at the precrosslinking step to come in contact with a surface of the substrate, and the step of sintering the substrate with which the precursor solution comes in contact and decomposing and removing the surface active agent.

According to such a structure, it is possible to provide an insulating film having a very high controllability, an excellent adhesion, a great mechanical strength and an ultimately low dielectric constant. Moreover, formation can be carried out at a low temperature. In particular, therefore, it is possible to form an insulating film having a high reliability without influencing a substrate comprising a compound semiconductor layer which is apt to be damaged at a high temperature.

According to such a structure, the surface active agent and the acid catalyst are dissolved in a solvent at a desired molar ratio, and the precursor solution is prepared in a mixing vessel and is applied onto the substrate, the silica derivative is polymerized by hydrolysis (a polycondensation reaction) (a precrosslinking step) to form a thin mesoporous silica film comprising a cavity in which the periodic autoagglutinin of the surface active agent is set to be a template, and the surface active agent of the template is completely decomposed thermally and removed at a sintering step, thereby forming a thin and pure mesoporous silica film. At this time, the substrate is exposed to a silica derivative atmosphere prior to the sintering and is dried with the supply of the silica derivative. Consequently, the contraction of the film by the hydrolysis can be suppressed and the cavity is exactly maintained without a destruction. In this state, it is possible to obtain a thin mesoporous silica film in which the strong autoagglutinin of the surface active agent is set to be the template. By the sintering step, the surface active agent of the template is completely decomposed thermally and removed so that a pure and thin mesoporous silica film can be obtained.

Thus, it is possible to provide an insulating film having a very high controllability, an excellent mechanical strength and an ultimately low dielectric constant. Moreover, formation can be carried out at a low temperature. Also in the case in which the insulating film is used as the interlayer insulating film of an integrated circuit as well as a portion provided under the pad, therefore, it is possible to form an insulating film having a high reliability without influencing the substrate.

Moreover, it is possible to properly change a vacancy rate by regulating the concentration of a precursor solution. Thus, it is possible to form an insulating thin film having a desirable dielectric constant with a very high workability.

Thus, an inorganic insulating film having a vacancy rate of 50% or more is formed and a dielectric constant can be more reduced than that in the addition of fluorine because air has a low dielectric constant. Thus, it is possible to extremely reduce the dielectric constant of the insulating film.

Furthermore, it is also possible to carry out formation in such a manner that the vacancy of the inorganic insulating film has a degree of orientation. Consequently, the vacancy has the degree of orientation and the periodic porous structure. Therefore, the mechanical strength can be increased. Thus, it is possible to obtain an insulating film having a high reliability.

Moreover, it is also possible to form the inorganic insulating film having a periodic porous structure including a cylindrical vacancy oriented in parallel with the surface of the substrate. Since the vacancy is oriented in parallel with the surface of the substrate, consequently, a low dielectric constant is uniformly given in a perpendicular direction to the surface of the substrate. In the case in which the inorganic insulating film is used as an interlayer insulating film, particularly, it is possible to employ such a structure as to be closed without an opening portion for an upper wiring and a lower layer (a substrate). Thus, it is possible to play a role of an effective thin film having a low dielectric constant which is excellent in a moisture resistance and has a high reliability.

Furthermore, there is included a plurality of periodic porous structure domains having a cylindrical vacancy oriented in one direction in parallel with the surface of the substrate, and the porous structure domains which are adjacent to each other can also be oriented in different directions from each other. Consequently, the porous structures are oriented in different directions for each domain. Therefore, it is possible to close the opening portions of the vacancies each other. Thus, it is possible to obtain a thin film having an ultimately low dielectric constant which has an excellent moisture resistance that is almost equal to the moisture resistance of a fine film and has an excellent mechanical strength with the periodic structure. Furthermore, a space between the layers is supported by the adjacent layer. Consequently, a layered periodic porous shape which is supposed to be usually unstable can be constructed with a stable and excellent mechanical strength.

Moreover, it is also possible to form the inorganic insulating film to be provided on the surface of the substrate and to include a periodic porous structure domain in which a layered vacancy is periodically oriented in one direction in parallel with the surface of the substrate. With this structure, furthermore, a higher vacancy rate can be obtained and a dielectric constant can be more reduced as compared with a structure having a cylindrical vacancy.

It is desirable that the processing step should include a step of coming in contact with silica derivative steam at such a temperature that the surface active agent is not decomposed thermally. Consequently, it is possible to form a thin film having a low dielectric constant which has a high vacancy rate and an excellent degree of orientation well without destroying a structure.

It is desirable that the processing step should be executed under the saturated vapor pressure of the silica derivative steam. Consequently, the processing is carried out under the saturated vapor pressure so that the sufficient silica derivative can efficiently be diffused from a surface. Thus, it is possible to form a thin film having a low dielectric constant which has a high vacancy rate and an excellent degree of orientation well without destroying a structure.

Moreover, a reaction rate can be enhanced by an increase in the partial pressure of the silica derivative or the pressure of the silica derivative.

It is desirable that the processing step should be executed at a temperature of a room temperature to 250° C. Consequently, the silica derivative can efficiently be supplied to the surface. In some cases in which the temperature is equal to or lower than the room temperature, a reactivity is deteriorated and the decomposition of the surface active agent is started when 250° C. is exceeded.

It is desirable that the processing step should be executed at a temperature of 90° C. to 200° C. Consequently, a reactivity can be enhanced and the diffusion of the silica derivative can progress well.

It is desirable that the processing step should be executed in the steam atmosphere of TEOS at 90° C. to 200° C. Consequently, it is possible to obtain a thin film having a low dielectric constant and a greater strength.

It is desirable that the processing step should be executed in the steam atmosphere of TMOS at 90° C. to 200° C. Consequently, it is possible to obtain a thin film having a low dielectric constant and a greater strength.

It is desirable that the substrate should be dipped in the precursor solution at the contact step. Consequently, it is possible to form an insulating film having a low dielectric constant with a high productivity.

Moreover, it is desirable that the substrate should be dipped in the precursor solution and should be pulled up at a desirable speed in the contact step. Consequently, it is possible to form an insulating film having a low dielectric constant with a high productivity.

It is desirable that the precursor solution should be applied onto the substrate at the contact step. Consequently, it is possible to form an insulating film having a low dielectric constant with a high productivity.

It is desirable that the contact step should be a spin coating step of dropping the precursor solution onto the substrate and rotating the substrate. Consequently, it is possible to easily regulate a film thickness and a vacancy rate and to form an insulating film having a low dielectric constant with a high productivity.

Moreover, it is desirable that the temperature of the precursor solution should be raised and a precrosslinking step of starting a crosslinking reaction should be included. By carrying out the precrosslinking, consequently, the crosslinking can efficiently progress and a thin film having a low dielectric constant and a high reliability can be formed at a high speed.

Furthermore, it is desirable that the temperature of the precursor solution should be raised and a precrosslinking step of starting a crosslinking reaction should be included, and the precursor solution starting a crosslinking reaction at the precrosslinking step should be caused to come in contact with the substrate prior to the contact step. According to such a method, the precrosslinking is carried out in advance and the precursor solution is then caused to come in contact with the surface of the substrate. Consequently, the crosslinking can efficiently progress and a thin film having a low dielectric constant and a high reliability can be formed at a high speed.

Moreover, it is also possible to carry out sintering while supplying the silica derivative. At the sintering step, moreover, the silica derivative is supplied from a vapor phase when the surface active agent of the template is to be decomposed thermally and removed. Consequently, the destruction of a structure can be suppressed and a strong, pure and thin mesoporous silica film can be obtained. In some cases in which a sediment is deposited on a surface, surface finishing may be carried out after the formation of the film.

### BRIEF DESCRIPTION OF THE DRAWINGS

FIG. 1 is a perspective view showing a surface emission type semiconductor laser device according to a first embodiment of the invention,

FIG. 2 is an enlarged sectional view showing the main part of the surface emission type semiconductor laser device illustrated in FIG. 1,

FIGS. 3(a) and 3(b) show the views showing a process for manufacturing the surface emission type semiconductor laser device according to the first embodiment of the invention,

FIG. 4 is an explanatory view showing an insulating film according to the first embodiment of the invention,

FIGS. 5(a) and 5(d) show the explanatory views showing a process for forming the insulating film according to the first embodiment of the invention,

FIGS. 6(a) to 6(d) show the explanatory views showing the insulating film according to the first embodiment of the invention,

FIG. 7 is a view showing a semiconductor laser device according to a second embodiment of the invention,

FIGS. 8(a) and 8(b) show the explanatory views showing a process for forming an insulating film according to a third embodiment of the invention,

FIG. 9 is an explanatory view showing an insulating film according to a fourth embodiment of the invention,

FIGS. 10(a) and 10(b) show the explanatory views showing an insulating film according to a fifth embodiment of the invention,

FIG. 11 is a perspective view showing a semiconductor laser device according to a conventional example, and

FIG. 12 is a sectional view showing the main part of the semiconductor laser device according to the conventional example.

### DESCRIPTION OF THE PREFERRED EMBODIMENTS

An embodiment of a semiconductor light emitting device and a method of manufacturing the semiconductor light emitting device according to the invention will be described in detail with reference to the drawings.

### First Embodiment

As a first embodiment of the invention, description will be given to a surface emission type semiconductor laser using, as an insulating layer, a thin film having a low dielectric constant formed by a method according to the invention.

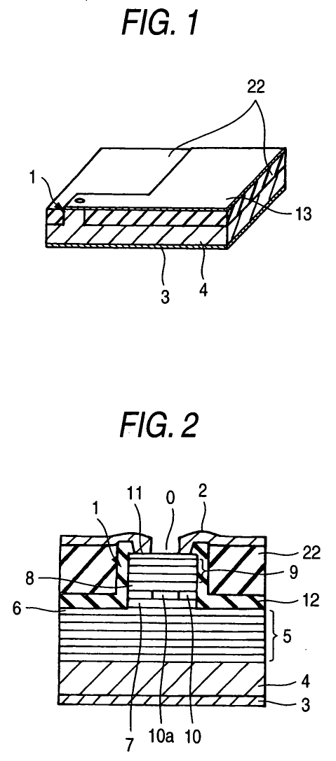

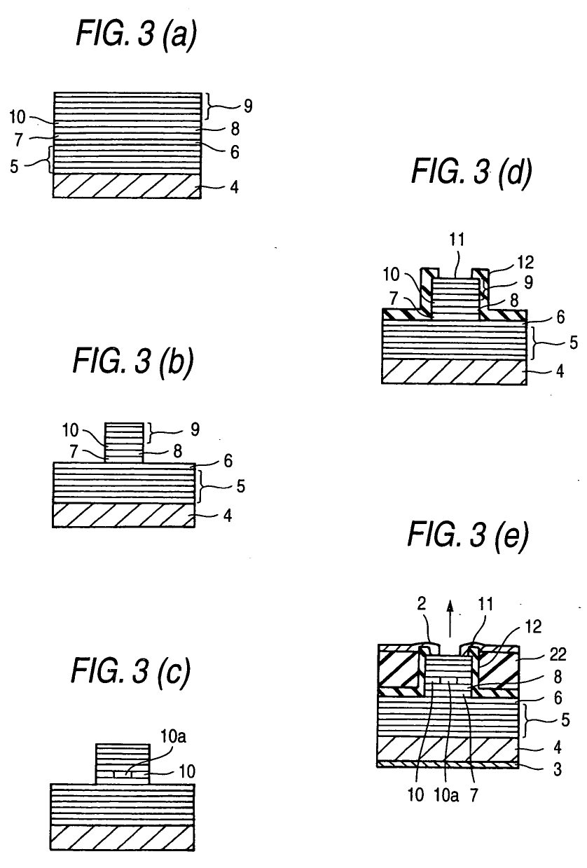

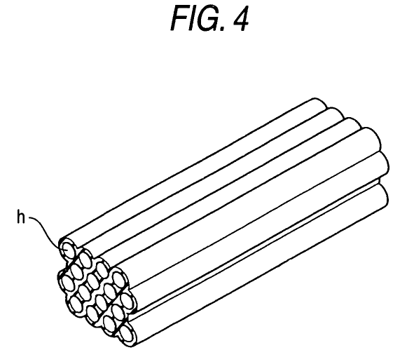

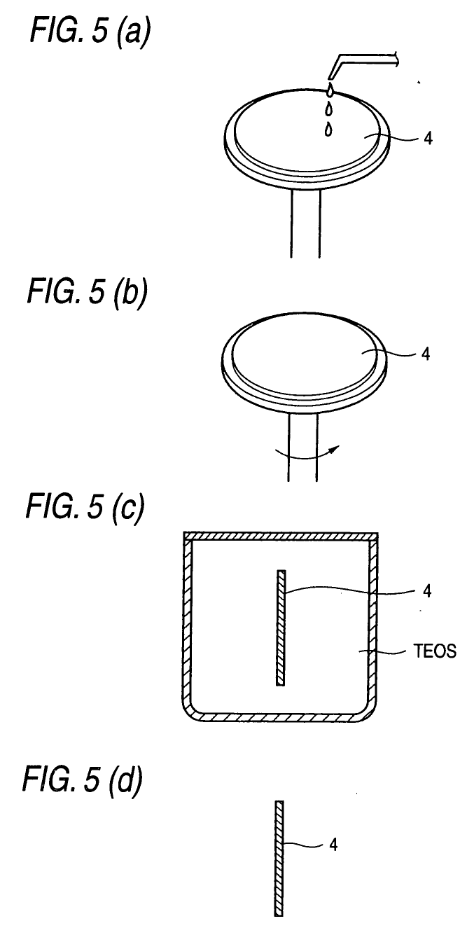

The surface emission type semiconductor laser according to the first embodiment of the invention is characterized in that an insulating film provided under a pad 13 is constituted by a thin film having a low dielectric constant as shown in FIG. 1 to be a perspective view, FIG. 2 to be an enlarged sectional view showing a main part, FIG. 3 to be a view showing a manufacturing process, and FIGS. 4 and 5 to be a typical view showing the structure of an insulating film according to the embodiment and a view showing a manufacturing process.

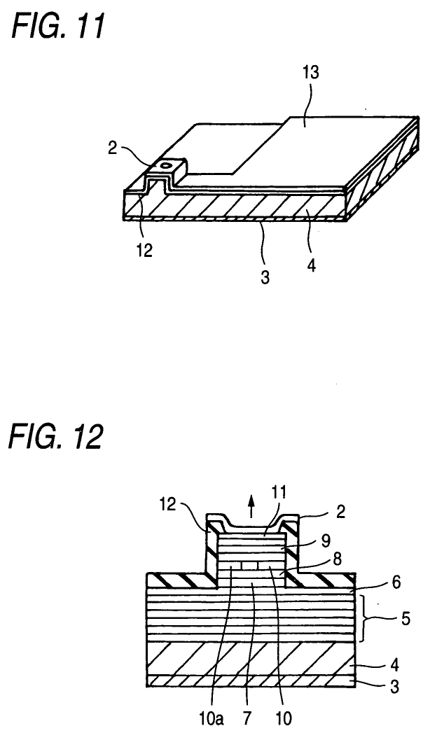

The structure of a mesa section to be a light emitting section is the same as that of the semiconductor laser according to the conventional example shown in FIGS. 11 and 12 and detailed description will be omitted. An insulating film having a low dielectric constant is constituted by a thin mesoporous silica film formed to include a plurality of periodic porous structure domains having a cylindrical vacancy h oriented in one direction in parallel with the surface of a substrate as shown in FIG. 4.

More specifically, a compound semiconductor laser 1 is constituted by a first electrode 3 formed by a Cr/Au structural film to be a two-layer structure including chromium and gold, a second electrode 2 formed by a Cr/Au structural film to be the two-layer structure including chromium and gold, and a mesa section formed by a plurality of compound semiconductor layers provided between the first electrode 3 and the second electrode 2. The compound semiconductor layer is constituted by a semiconductor substrate 4 comprising N⁺-GaAs, a lower multilayer reflecting film 5 forming a multilayer structural film such as AlₓGa₁₋ₓAs provided on the upper surface of the semiconductor substrate 4, a quantum well active layer 7 formed on the upper surface of the lower multilayer reflecting film 5 through a lower clad layer 6 comprising Al_{y}Ga_{1-y}As, and an upper multilayer reflecting film 9 comprising AlᵣGa₁₋ᵣAs formed on the upper surface of the quantum well active layer 7 through an upper clad layer 8 comprising AlᵤGa₁₋ᵤAs. Moreover, a current constricting layer 10 formed by an AlGaAs oxide layer which is opened over a predetermined width and has a current constricting section 10a is provided on the upper clad layer 8. Furthermore, the second electrode 2 is formed through a contact layer 11 formed on the upper multilayer reflecting film 9 and comprising AlᵣGa₁₋ᵣAs doped in a high concentration, and the first electrode 3 is formed on a surface of the semiconductor substrate 4 where an electrode is to be formed.

The mesa section thus formed is covered with a thin insulating film 12 formed of polyimide, an insulating film formed by a thin film 22 having a low dielectric constant is provided on the insulating film 12, and an electrode pad 13 connected to the second electrode 2 formed on the top surface of the mesa section is provided. The second electrode 2 is constituted in a ring-shaped pattern having an opening portion on a center and can take out a light from the opening portion.

Such a semiconductor laser 1 is fabricated by the following method, for example.

First of all, as shown in FIG. 3(a), semiconductor layers excluding the first electrode 3 and the second electrode 2 are sequentially provided on the surface of the n⁺-GaAs substrate 4 by an MOCVD method.

As shown in FIG. 3(b), then, each of layers provided on the upper clad layer 8 is subjected to patterning by reactive dry etching by setting a resist pattern formed by photolithography as a mask.

As shown in FIG. 3(c), thereafter, heating is carried out in a steam atmosphere and the current constricting layer 10 is obtained by introducing steam from the end face of an element and oxidizing an aluminum arsenide film to form aluminum oxide (Al₂O₃). A portion in which the steam oxidation does not occur (a portion in which aluminum arsenide remains) acts as a current constricting section 10a.

As shown in FIG. 3(d), subsequently, a thin film having a low dielectric constant to be an interlayer insulating film 22 is formed by the following method and a contact is formed thereon. As shown in FIG. 3(e), the second electrode 2 is formed to come in contact with the top surface of the mesa section to be a light emitting surface. Then, the first electrode 3 is formed and a wiring section including an electrode pad 13 is formed.

In a method of forming a thin film having a low dielectric constant, a precursor solution is supplied to the surface of a substrate and is left overnight at 90° C. in order to carry out precrosslinking, and is then left overnight in a TEOS atmosphere at 180° C., silica steam is diffused into the film and a rigid state is brought to carry out sintering, thereby forming a thin film having a low dielectric constant and a high reliability.

In this method, a thin mesoporous silica film is formed to include a plurality of periodic porous structure domains having a cylindrical vacancy oriented in one direction in parallel with the surface of the substrate (FIG. 4).

More specifically, as shown in FIG. 5(a), cetyltrimethylammonium bromide (CTAB: C₁₆H₃₃N+(CH₃)₃BR—) of a cation type to be a surface active agent, tetramethoxy silane (TMOS) to be a silica derivative and hydrochloric acid (HCl) to be an acid catalyst are first dissolved in an H₂O/alcohol mixed solvent and a precursor solution is prepared in a mixing vessel. For a molar ratio of the preparation of the precursor solution, 0.05 of the surface active agent, 0.1 of the silica derivative and 2 of the acid catalyst are mixed for 100 of the solvent (after a viscosity is prepared if necessary), and the mixed solution is put on a spinner and is dropped onto the substrate 4 on which the surface emission type laser is formed.

As shown in FIG. 5(b), a rotation is carried out at 500 to 5000 rpm to apply the precursor solution in a desirable thickness. The substrate 4 subjected to the application is held overnight at 90° C. to polymerize the silica derivative by hydrolysis (a polycondensation reaction) (a precrosslinking step), thereby forming a thin mesoporous silica film in which the periodic autoagglutinin of the surface active agent is set to be a template.

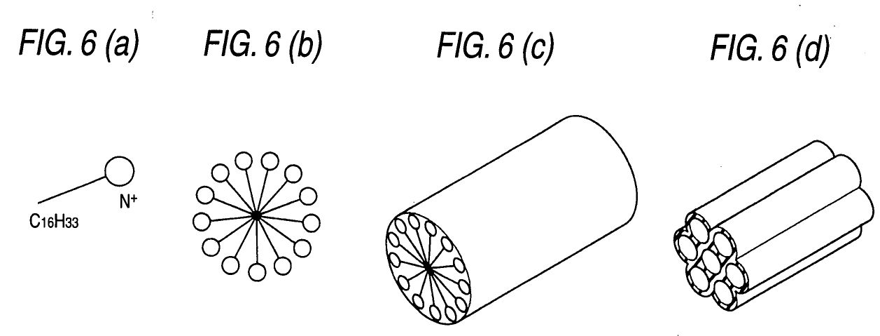

As shown in FIG. 6(a), the autoagglutinin forms a spherical micell structure (FIG. 6(b)) in which a plurality of molecules having C₁₆H₃₃N⁺(CH₃)₃Br⁻ is set to be one molecule. Thus, the degree of aggregation is enhanced with an increase in a concentration.

As shown in FIG. 5(c), then, the substrate 4 is dried overnight in a saturated TEOS atmosphere at 180° C.

Thereafter, the substrate 4 thus dried is heated and sintered in an oxygen atmosphere at 400° C□ for 3 hours and the surface active agent of the template is completely decomposed thermally and removed to form a pure and thin mesoporous silica film as shown in FIG. 5(d).

According to such a method, when the degree of aggregation is enhanced with an increase in a concentration, a portion from which a methyl group falls off becomes hollow (FIG. 6(c)). By exposure into the saturated TEOS atmosphere at 180□ in this state (FIG. 5(c)), the cavity is not destroyed but maintained as it is, and is dried and then sintered in this condition (FIG. 5(d)).

Consequently, a cylinder having a cylindrical vacancy oriented is formed (FIG. 6(d)) so that a thin film having a lower dielectric constant can be formed. Thus, it is apparent that the thin film having a low dielectric constant is formed by a porous thin film having a vacancy oriented.

In this way, the semiconductor light emitting device comprising the thin film 22 having a low dielectric constant according to the embodiment of the invention is formed.

According to the method of the embodiment in accordance with the invention, the crosslinking reaction progresses well by the processing in the TEOS steam atmosphere and the strength of the structure is enhanced and is maintained without a decay in the sintering. As a result, a diffraction peak is coincident and the sintering is completed well without the decay of a crystal structure. Consequently, a great mechanical strength can be obtained.

According to such a structure, since the vacancy is oriented well in parallel with the surface of the substrate, the pad insulating film has a strength increased, uniformly has a low dielectric constant in a perpendicular direction to the surface of the substrate, and particularly, can have such a close structure as to provide no opening portion for a pad wiring to be an upper layer and a lower substrate. Thus, it is possible to obtain an effective thin film having a low dielectric constant which is excellent in a moisture resistance and has a great mechanical strength and a high reliability. Accordingly, a pad capacity can be reduced considerably and high-speed modulation can be carried out, and a leakage current is not generated and an interlayer insulating film having a long lifetime can be thus obtained.

While the film is exposed to the TEOS steam atmosphere prior to the sintering in the embodiment, the silica derivative to be used as the steam atmosphere is not restricted to the TEOS (tetraethoxy silane) but a silicon alkoxide material such as TMOS (tetra-methoxy silane) is desirably used.

Moreover, a silica derivative having the following structural formula can be used in addition to the TEOS and the TMOS.

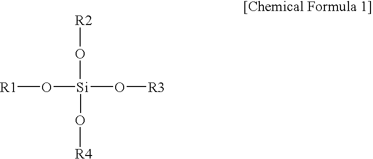

Rn (n=1, 2, 3, 4 . . . ) represents a saturated chain hydrocarbon type such as CH₃ or C₂H₅, an unsaturated chain hydrocarbon type or an aromatic type such as a benzene ring or saturated cyclic hydrocarbon such as cyclohexane, and R1, R2, R3 and R4 may be identical to or different from each other.

Furthermore, R1 may be used as the silica derivative to be used in the process in place of “R1-o” in the chemical formula.

More desirably, “R1”, “R2”, “R3” and “R4” maybe substituted for first to third atomic groups in functional groups of “R1-O”, “R2-O”, “R3-O” and “R4-O”, respectively. An example is shown in the following formula.

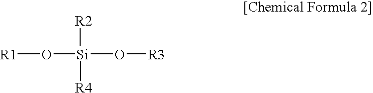

By using such a silanizing agent as steam, it is possible to construct a mesoporous silica film having a very excellent moisture resistance in addition to characteristics of a great strength and a high adhesion.

Moreover, the composition of the precursor solution is not restricted to the composition according to the embodiment but it is desirable that 0.1 to 5 of the surface active agent, 0.1 to 10 of the silica derivative and 0 to 5 of the acid catalyst should be used for 100 of the solvent. By using the precursor solution having such a structure, it is possible to form an insulating film having a low dielectric constant which includes a cylindrical vacancy.

Moreover, while the cation ion type cetyltrimethylammonium bromide (CTAB: C₁₆H₃₃N⁺(CH₃)₃Br⁻) is used as the surface active agent in the embodiment, it is not restricted. It is apparent that another surface active agent may be used.

If an alkali ion such as an Na ion is used as a catalyst, a semiconductor material is deteriorated. For this reason, it is desirable that a cation ion type surface active agent should be used and an acid catalyst should be used as a catalyst. For the active catalyst, an inorganic catalyst such as nitric acid (HNO₃), sulfuric acid (H₂SO₄), phosphoric acid (H₃PO₄) or H₄SO₄ may be used in addition to HCl. Moreover, it is also possible to use an organic acid catalyst such as carboxylic acid, sulfonic acid, sulfinic acid or phenol.

Furthermore, the silica derivative to be used as a raw material is not restricted to the TMOS but it is desirable that a silicon alkoxide material such as tetraethoxy silane (TEOS) should be used.

Moreover, while the water H₂O/alcohol mixed solvent has been used for the solvent, only the water can be used.

In addition, while the oxygen atmosphere has been used for the sintering atmosphere, an atmosphere, a reduced pressure and a nitrogen atmosphere can also be used. Desirably, it is possible to enhance a moisture resistance and to reduce a leakage current by using a foaming gas comprising a mixed gas of nitrogen and hydrogen.

Moreover, it is possible to properly change the mixing ratio of the surface active agent, the silica derivative, the acid catalyst and the solvent.

Furthermore, while the prepolymerizing step is carried out overnight at 90° C., it is possible to properly carry out a selection within a range of 30° C. to 150° C. for 1 to 120 hours. It is desirable that 60° C. to 120° C., and furthermore, 90° C. should be selected.

Moreover, it is preferable that the step of exposing the TEOS under a saturated vapor pressure at 180° C. should be carried out for approximately one to three nights. In addition, it is also possible to shorten a time by supplying the TEOS steam from the outside into a vessel, increasing the partial pressure of the TEOS and raising a process temperature. Since the exposure to the steam of the silica derivative is enough, furthermore, the temperature is not restricted to 180° C. but may be 90° C. or less. Moreover, it is preferable that an upper limit should be the starting temperature (200° C. to 250° C.) of the thermal decomposition of the surface active agent or less.

While the sintering step is carried out at 400° C. for 1 hour, furthermore, it may be performed for approximately 1 to 5 hours at 300° C. to 500° C. It is desirable that 350° C. to 450° C. should be set.

In addition, while the TEOS is exposed under the saturated vapor pressure prior to the sintering in the embodiment, the sintering may be carried out in the steam atmosphere of the silica derivative such as the TEOS. In this case, a sediment such as oxide is sometimes deposited on the surface. In that case, it is preferable to remove the sediment by carrying out the surface finishing after the sintering.

### Second Embodiment

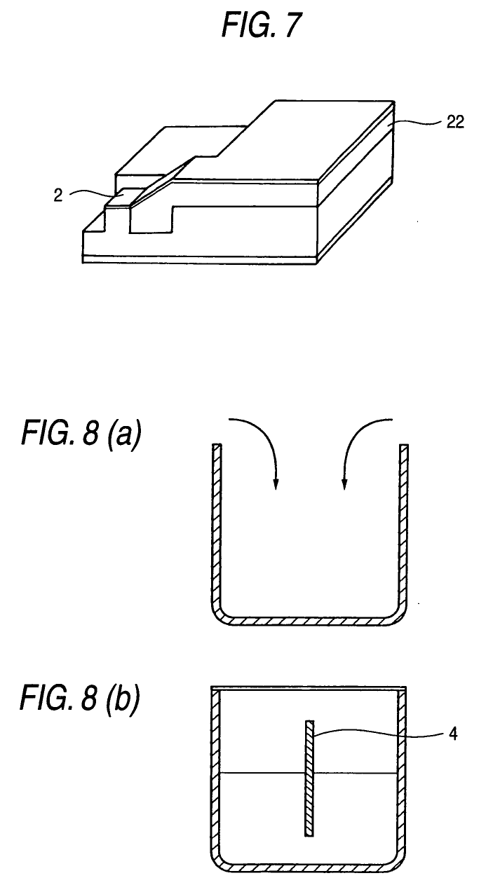

While the surface emission type semiconductor laser having the mesa structure has been described in the first embodiment, this is not restricted but the invention can also be applied to a surface emission type semiconductor laser having a trench structure shown in FIG. 7.

This structure is characterized in that the mesa section in the first embodiment is surrounded by a trench and the trench is filled with the thin film 22 having a low dielectric constant. 2 denotes an electrode.

With such a structure, it is also possible to provide a surface emission type semiconductor laser in which the mechanical strength of the mesa section can be increased and a pad capacity can be reduced.

For a dip coating method, a method of dropping a precursor solution onto a substrate is also effective in addition to the method described above.

### Third Embodiment

While the thin mesoporous silica film is formed by carrying out the spin coating method over the precursor solution in the first embodiment, the spin coating method is not restricted but a dipping method may be carried out as shown in FIGS. 8(a) and 8(b).

In the same manner as in the embodiment, as shown in FIG. 8(a), mixing is carried out to prepare a precursor solution and a substrate 4 having the mesa section formed thereon is dipped in the solution as shown in FIG. 8(b). The substrate 4 subjected to the application is held overnight at 90° C. to polymerize the silica derivative by hydrolysis (a polycondensation reaction) (a precrosslinking step), thereby forming a thin mesoporous silica film in which the periodic autoagglutinin of a surface active agent is set to be a template.

In the same manner as in the first embodiment, finally, the substrate 4 is held for two nights at 90° C. to polymerize the silica derivative by a hydrolysis and polycondensation reaction, and is then dried for one night in a saturated TMOS atmosphere at 180° C. Lastly, the substrate 4 is heated and sintered in an oxygen atmosphere for 3 hours at 400° C. and the surface active agent of the template is completely decomposed thermally and removed to form a pure and thin mesoporous silica film.

According to such a construction, a periodic porous structure is employed. Therefore, a mechanical strength can be increased so that an insulating film having a high reliability can be obtained. Moreover, since a vacancy is oriented in parallel with the surface of the substrate, a low dielectric constant is uniformly given in a perpendicular direction to the surface of the substrate. In the case in which the insulating film is used as an interlayer insulating film, therefore, it is possible to employ such a structure as to be closed without an opening portion for an upper wiring and a lower wiring. Thus, it is possible to play a role of an effective thin film having a low dielectric constant which is excellent in a moisture resistance and has a high reliability.

### Fourth Embodiment

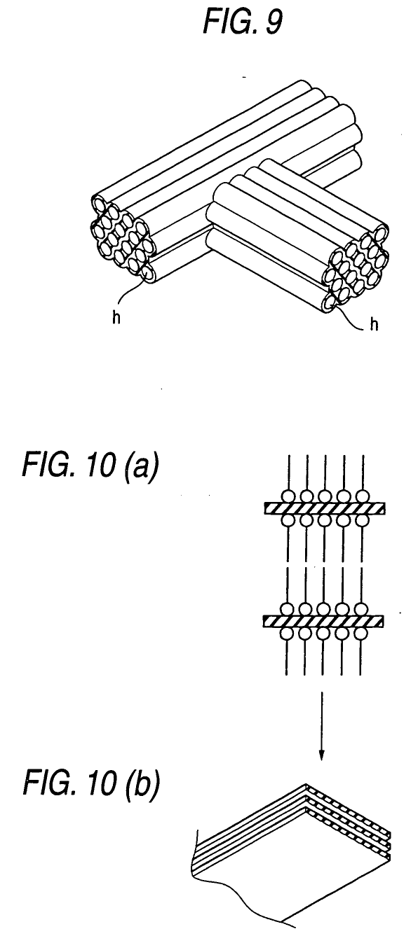

While the description has been given to the insulating film in which a plurality of periodic porous structure domains including a cylindrical vacancy oriented in one direction is provided and the adjacent porous structure domains are oriented in different directions from each other in the embodiments, it is also possible to form an insulating film in such a manner that a vacancy h is oriented in the same direction over the whole surface of a substrate as shown in FIG. 9.

### Fifth Embodiment

Furthermore, a structure in which a vacancy h is oriented like a layer is also effective as shown in FIGS. 10(a) and 10(b). In addition, formation is carried out by an increase in the concentration of a surface active agent in a precursor solution and other steps are the same as those in the first to fourth embodiments.

When the concentration of the surface active agent is further increased in the structure shown in FIG. 6(c), a molecule is oriented like a layer as shown in FIG. 10(e) and there is formed an insulating film having a low dielectric constant in which the vacancy h shown in FIG. 10(f) is oriented like a layer. With this structure, it is possible to more increase a vacancy rate and to more reduce a dielectric constant than those of a structure having a cylindrical vacancy.

It is apparent that the construction of the obtained structure is changed depending on the ratio of a surface active agent and a silica derivative when a precursor solution is to be prepared.

For example, it is apparent that a three-dimensional network structure (cubic) is obtained when the molar ratio of the surface active agent and the silica derivative, for example, CATB/TEOS is 0.3 to 0.8. If the molar ratio is lower, that is, 0.1 to 0.5, it is possible to obtain an insulating film having a low dielectric constant which includes a cylindrical vacancy oriented. On the other hand, if the molar ratio is higher, that is, 0.5 to 2, it is possible to obtain an insulating film having a low dielectric constant which includes a layered vacancy oriented.

While the spin coating method using a spinner has been described in the embodiments, a so-called brush coating method of carrying out coating by means of a brush can also be applied.

Moreover, the precrosslinking step is carried out prior to the contact step with a substrate, for example, coating or dipping so that the precursor solution generating the precrosslinking reaction can be caused to come in contact with the substrate. Moreover, the precrosslinking may be carried out after the precursor solution is caused to come in contact with the substrate.

In addition, while the pad insulating film of the surface emission type semiconductor laser has been described in the embodiments, the invention can also be applied to a semiconductor light emitting device to be a high-speed device in which a device using a compound semiconductor such as HEMT is integrated in the outside region of a semiconductor laser which is isolated from the semiconductor laser at the trench in the second embodiment, for example.

As described above, according to the invention, a thin film having a low dielectric constant is formed on the insulating film of a semiconductor light emitting unit such as a semiconductor laser. Therefore, it is possible to provide a semiconductor light emitting unit capable of reducing a pad capacity and carrying out a high-speed operation.

Since a mechanical strength is also high, which brings about a high reliability.

1. A semiconductor light emitting device comprising:
a mesa section having at least a sandwich structure of an n-type clad layer, an active layer and a p-type clad layer which are constituted by compound semiconductor layers formed on a substrate; and
an inorganic insulating film formed to cover the mesa section excluding a contact region, wherein the inorganic insulating film is constituted by an inorganic insulating film having a vacancy rate of 50% or more.

2. The semiconductor light emitting device according to claim 1, wherein the inorganic insulating film includes a vacancy having a degree of orientation.

3. The semiconductor light emitting device according to claim 2, wherein the inorganic insulating film includes an inorganic insulating film having at least two kinds of periodic porous structures.

4. The semiconductor light emitting device according to claim 1, wherein the mesa section includes a surface emission structure having an electrode in a top portion and comprises a semiconductor layer provided with an active layer having a quantum well structure constituted by a compound semiconductor, and
a pad to come in contact with the electrode is provided on the inorganic insulating film.

5. A method of manufacturing a semiconductor light emitting device including a mesa section have at least a sandwich structure of an n-type clad layer, an active layer and a p-type clad layer which are constituted by compound semiconductor layers formed on a substrate, and an inorganic insulating film formed to cover the mesa section excluding a contact region,
the step of forming the inorganic insulating film comprising:
the step of generating a precursor solution containing a silica derivative and a surface active agent;
the precrosslinking step of raising a temperature of the precursor solution and starting a crosslinking reaction;
the contact step of causing the precursor solution starting the crosslinking reaction at a precrosslinking step to come in contact with a surface of the substrate; and
the step of sintering the substrate with which the precursor solution comes in contact and decomposing and removing the surface active agent, an insulating film being thus formed.

6. The method of manufacturing a semiconductor light emitting device according to claim 5, wherein the substrate is dipped in the precursor solution at the contact step.

7. The method of manufacturing a semiconductor light emitting device according to claim 5, wherein the substrate is dipped in the precursor solution and is pulled up at a desirable speed in the contact step.

8. The method of manufacturing a semiconductor light emitting device according to claim 5, wherein the precursor solution is applied onto the substrate at the contact step.

9. The method of manufacturing a semiconductor light emitting device according to claim 8, wherein the contact step is a spin coating step of dropping the precursor solution onto the substrate and rotating the substrate.

10. The semiconductor light emitting device according to claim 2, wherein the mesa section includes a surface emission structure having an electrode in a top portion and comprises a semiconductor layer provided with an active layer having a quantum well structure constituted by a compound semiconductor, and
a pad to come in contact with the electrode is provided on the inorganic insulating film.

11. The semiconductor light emitting device according to claim 3, wherein the mesa section includes a surface emission structure having an electrode in a top portion and comprises a semiconductor layer provided with an active layer having a quantum well structure constituted by a compound semiconductor, and
a pad to come in contact with the electrode is provided on the inorganic insulating film.
